(19) United States
(12) Patent Application Publication
(10) Pub. No.: US 2025/0275478 A1
(43) Pub. Date: Aug. 28, 2025

(54) DEVICE STRUCTURE AND MANUFACTURING METHOD THEREOF

(71) Applicant: Taiwan Semiconductor Manufacturing Company, Ltd., Hsinchu (TW)

(72) Inventors: Sheng-Han Yi, Hsinchu City (TW); Hsing-Lien Lin, Hsinchu City (TW)

(73) Assignee: Taiwan Semiconductor Manufacturing Company, Ltd., Hsinchu (TW)

(21) Appl. No.: 18/590,884

(22) Filed: Feb. 28, 2024

(51) Int. Cl. H10N 30/50; H10N 30/063; H10N 30/074; H10N 30/853; H10N 30/87

(52) U.S. Cl. CPC H10N 30/50; H10N 30/063; H10N 30/074; H10N 30/8554; H10N 30/871

(57) ABSTRACT

A stack structure and the manufacturing methods thereof are provided. The structure includes a first electrode material layer, a first piezoelectric layer disposed over the first electrode material layer, a second electrode material layer disposed over the first piezoelectric layer, a second piezoelectric layer disposed over the second electrode material layer, and a third electrode material layer disposed over the second piezoelectric layer. A first oxygen-containing interface is formed between the first piezoelectric layer and the second electrode material layer, and a first lattice-matching interface is formed between the first piezoelectric layer and the first electrode material layer. A second oxygen-containing interface is formed between the second piezoelectric layer and the third electrode material layer, and a second lattice-matching interface is formed between the second piezoelectric layer and the second electrode material layer.

### BACKGROUND

Microscopic mechanical and/or electronic devices formed through MEMS (micro-electromechanical system) technology are MEMS devices, and it is compatible to fabricate MEMS devices using semiconductor manufacturing processes through semiconductor device (such as CMOS) fabrication technologies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 7 illustrate schematic cross-sectional views showing a stacking structure at various stages of a manufacturing method for forming a semiconductor device according to some embodiments of the present disclosure.

FIG. 8 is a schematic cross-sectional view showing a stacking structure for a semiconductor device according to some embodiments of the present disclosure.

FIG. 9 to FIG. 11 illustrate schematic cross-sectional views showing a structure at various stages of a manufacturing method for forming a semiconductor device according to some embodiments of the present disclosure.

FIG. 12 is a schematic top view of an exemplary structure with MEMS devices arranged in arrays in accordance with embodiments of the present disclosure.

FIG. 13 is a schematic illustration of working principles of an exemplary MEMS micro speaker structure in accordance with embodiments of the present disclosure.

FIG. 14 is a schematic cross-sectional view of an exemplary structure having MEMS devices connected with a device wafer in accordance with some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The embodiments of the present disclosure describe the exemplary manufacturing processes of a stack structure and MEMS device structures having the same. Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure. The embodiments are intended to provide further explanations but are not used to limit the scope of the present disclosure.

Embodiments of the present disclosure are directed to micro-electro mechanical system (MEMS) devices having stacking structures containing piezoelectric thin films. For example, the MEMS device may include a moving membrane (i.e., vibrating membrane) or a diaphragm that is driven by the piezoelectric actuation of the device. The optimal condition for operation of the movable element may involve a gas ambiance or atmosphere contained in a space or enclosed by a cavity. Various embodiments described herein provide a stacked structure with two or more piezoelectric thin films sandwiched between multiple-layered composite thin films. An increased sound pressure level is achieved through the two or multiple piezoelectric films used in the device. The stacking structure having the stacking films stacked upon and between the multiple piezoelectric thin films offers better TDDB (time dependent dielectric breakdown) performance and less polarization fatigue, leading to extended lifetime and enhanced performance for some types of MEMS devices, such as a MEMS micro speaker.

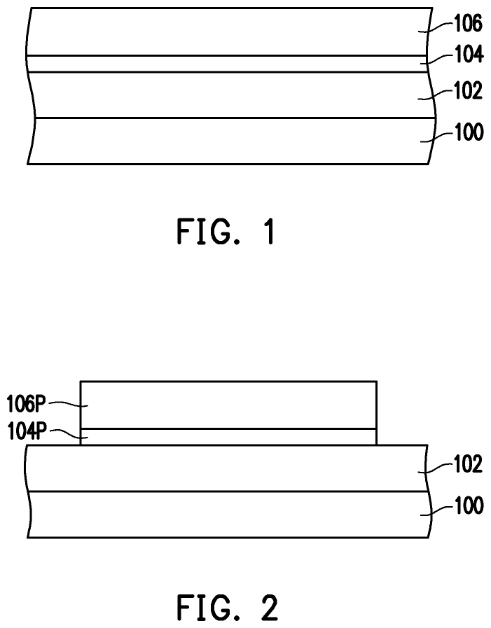

FIG. 1 to FIG. 7 illustrate schematic cross-sectional views showing a stacking structure at various stages of a manufacturing method for forming a semiconductor device according to some embodiments of the present disclosure. Through the schematic figures, an exemplary stacking structure for forming a MEMS device structure is illustrated in accordance with some embodiments of the present disclosure.

Referring to FIG. 1, in some embodiments, a substrate 100 is provided, and a base insulation layer 102, an oxide material layer 104 and an electrode material layer 106 are sequentially formed on the substrate 100. In some embodiments, the substrate 100 includes a semiconductor substrate, and the semiconductor substrate may be a monocrystalline semiconductor substrate of silicon, an elemental semiconductor such as germanium; a suitable compound semiconductor such as silicon carbide (SiC), indium arsenide (InAs), or indium phosphide (InP), or a suitable alloy semiconductor such as silicon-germanium (SiGe), gallium arsenic phosphide (GaAsP), or gallium indium phosphide (GaInP). In some embodiments, the substrate 100 is or includes a silicon-on-insulator (SOI) substrate, silicon-germanium on insulator (SGOI) or a germanium-on-insulator (GOI) substrate. In some embodiments, the substrate 100 may be a silicon wafer, a SOI wafer, or a bulk wafer made of other semiconductor materials such as III-V semiconductor materials such as gallium nitride (GaN) or gallium arsenide (GaAs).

In some embodiments, the base insulation layer 102 includes an insulating oxide material such as silicon oxide, organosilicate glass, a porous low-k dielectric material, or a spin-on glass (SOG) material. Other suitable materials within the contemplated scope of disclosure may also be used. In some embodiments, the base insulation layer 102 may be formed by chemical vapor deposition (CVD), physical vapor deposition (PVD), thermal oxidation or spin-on coating. In some embodiments, the material of the base insulation layer 102 includes silicon oxide formed by CVD processes using tetraethoxysilane (TEOS). The thickness of the base insulation layer 102 may range from nanometers to micrometers depending on product designs. In some embodiments, the oxide material layer 104 includes a metal oxide material such as titanium oxide. Other suitable materials within the contemplated scope of disclosure may also be used. In some embodiments, the oxide material layer 104 may be formed by PVD (such as sputtering) or CVD. In one embodiment, the oxide material layer 104 may be a titanium oxide layer formed by forming a titanium layer and then oxidizing into the titanium oxide layer by thermal oxidation. For example, the oxide material layer 104 may function as an adhesion layer promoting the adhesion between the base insulation layer 102 and the electrode material layer 106.

In some embodiments, the electrode material layer 106 includes a layer of one or more metals such as platinum (Pt), ruthenium (Ru), iridium (Ir), lanthanum (La), nickel (Ni) or the oxides thereof. In some embodiments, the electrode material layer 106 includes a metallic material such as platinum (Pt) or ruthenium (Ru). In some embodiments, the electrode material layer 106 includes a metal oxide material such as ruthenium oxide (RuOx, 1≤x≤2), iridium oxide (IrOx, 1≤x≤2), or lanthanum nickel oxide (LaNiOx, 1≤x≤3). In some embodiments, the electrode material layer 106 includes a metallic material, a metal oxide material, a combination thereof, a composite thereof or a stack thereof. In certain embodiments, the electrode material layer 106 is or includes a platinum layer. In certain embodiments, the electrode material layer 106 is or includes a ruthenium oxide layer. For example, the thickness of the electrode material layer 106 should be thick enough to be equivalent to or larger than 500 angstroms. In one embodiment, the thickness of the electrode material layer 106 ranges from about 500 angstroms to 2000 angstroms. In some embodiments, the composite structure of the electrode material layer 106 and the oxide material layer 104 may be regarded as a composite electrode stack. In some other embodiments, the electrode material layer 106 itself may be regarded as the bottom electrode structure.

Referring to FIG. 2, a patterning process is performed to pattern the electrode material layer 106 and the oxide material layer 104 respectively into the electrode material pattern 106P and the oxide material pattern 104P. In some embodiments, the patterning process includes forming a photoresist layer (not shown) with a pattern over the electrode material layer 106, etching the underlying electrode material layer 106 and the oxide material layer 104 by transferring the pattern of the photoresist layer to pattern the underlying electrode material layer 106 and the oxide material layer 104, and the photoresist layer may be subsequently removed, for example, by ashing or other suitable processes.

In some embodiments, the electrode material pattern 106P and the oxide material pattern 104P are patterned through a single patterning process and to have the same dimensions. However, it is possible that the electrode material pattern 106P and the oxide material pattern 104P are patterned through different patterning processes and may have different dimensions.

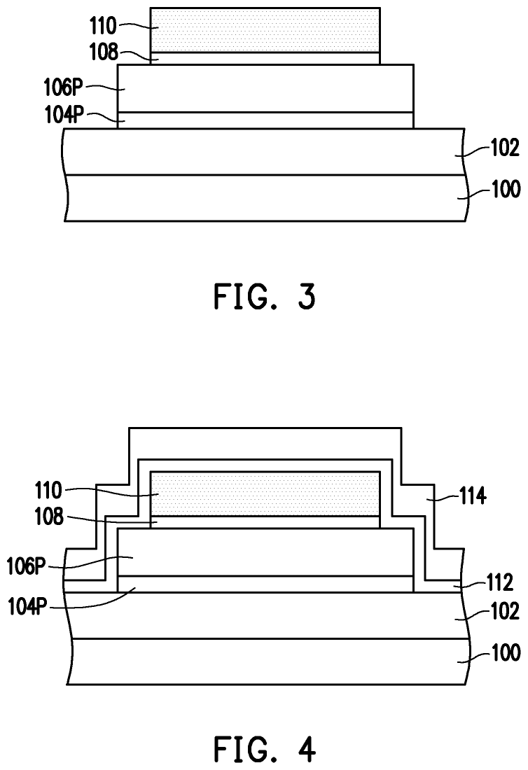

Referring to FIG. 3, in some embodiments, a buffer layer 108 is formed on the electrode material pattern 106P and a piezoelectric layer 110 is then formed on the buffer layer 108. In some embodiments, the buffer layer 108 is formed by PVD or CVD. Examples of the material for the buffer layer 108 include metals such as lanthanum and nickel, oxides thereof and composite oxides thereof. The buffer layer 108 may be formed as a single-layer structure of the material(s), or a stack structure of a plurality of materials. In some embodiments, the buffer layer 108 includes a layer of lanthanum nickel oxide (LaNiOx, 1≤x≤3). For example, the buffer layer 108 is formed before the formation of the piezoelectric layer 110 to provide crystalline orientation preferred for the later formed piezoelectric material of the piezoelectric layer 110. In some embodiments, the buffer layer 108 includes a layer of lanthanum nickel oxide having perovskite crystal structure, which offers similar perovskite structure and smaller lattice mismatch and preferentially orients the crystals of the piezoelectric material constituting the piezoelectric layer 110 in the predetermined orientation such as (100) orientation. Through the orientation inducing capability, it improves the crystal orientation (e.g. (100) orientation) and increases the piezoelectric coefficient (d₃₃) of the piezoelectric layer 110. Also, the hardness of the piezoelectric layer 110 may be modified.

Referring to FIG. 3, in some embodiments, the piezoelectric layer 110 includes a lead-containing piezoelectric material. For example, the lead-containing piezoelectric material includes lead zirconium titanate (also called lead zirconate titanate and abbreviated as PZT) with the chemical formula Pb[Zr_{X}Ti_{(1-X)}]O₃ (0<x<1), either undoped or doped with niobium (Nb), lanthanum (La), or iron (Fe). In some embodiments, the piezoelectric layer 110 is formed by, for example, PVD including sputtering, laser ablation, or pulse laser deposition (PLD) or CVD. In some embodiments, the piezoelectric layer 110 is formed by, for example, wet/chemical methods using so-gel or aerosol deposition and thermally annealing at a high temperature. In addition, as a piezoelectric material, lead zirconium titanate is useful for actuator applications as it physically changes its shape when an external electric field is applied. In some embodiments, the piezoelectric layer 110 may be formed through various available methods as long as the piezoelectric layer 110 is formed in the preferred crystal orientation (e.g. oriented in the (100) orientation). For example, the piezoelectric layer 110 be formed with a thickness ranging from about 500 nanometers to 1000 nanometers.

For a crystalline material, the lattice parameters of the crystalline substance can be expressed by, for example, lattice constant a, b or c, physical dimensions that determine the geometry of the unit cells in a crystal lattice, and is proportional to the distance between atoms in the crystal. In some embodiments, among the electrode material layer 106, the buffer layer 108 and the piezoelectric layer 110, the material of the buffer layer 108 has the value of the lattice parameter (e.g. lattice constant a) larger than that of the material of the electrode material layer 106 and smaller than that of the material of the piezoelectric layer 110. For example, the lattice constant a of the buffer layer 108 being a LaNiOx layer is larger than the lattice constant a of the electrode material layer 106 being a Pt layer and smaller than the lattice constant a of the piezoelectric layer 110 being a PZT layer. Through arranging the buffer layer 108 interfacing the electrode material layer 106 and the piezoelectric layer 110, better lattice matching is achieved and the quality of the piezoelectric layer 110 is enhanced and the piezoelectric coefficient of the formed piezoelectric layer 110 is increased. For the possible MEMS devices, the micro speaker device using the piezoelectric film of a larger piezoelectric coefficient offers a higher sound pressure level (SPL) and a larger sound intensity.

Although not expressly described, it is understood that the buffer layer 108 and the piezoelectric layer 110 may be formed with the same pattern, and the buffer layer 108 and the piezoelectric layer 110 may be formed as blanket layers and then patterned through a single patterning process and to have the same dimensions. However, it is possible that the buffer layer 108 and the piezoelectric layer 110 may be formed with different patterns, and the buffer layer 108 and the piezoelectric layer 110 may be formed as blanket layers and then patterned through different patterning processes for different dimensions. In certain embodiments, the patterning of the piezo electric layer 110 involves wet etching.

Referring to FIG. 4, in some embodiments, a metal oxide material layer 112 and an electrode material layer 114 are sequentially formed over the stack of the oxide material pattern 104P, the electrode material pattern 106P, the buffer layer 108 and the piezoelectric layer 110. Referring to FIG. 4, the metal oxide material layer 112 and the electrode material layer 114 are globally formed and are formed conformally covering the underlying stack (conformal to the profiles of the stack of the oxide material pattern 104P, the electrode material pattern 106P, the buffer layer 108 and the piezoelectric layer 110).

In some embodiments, the metal oxide material layer 112 may be formed by PVD (such as sputtering) or CVD. In some embodiments, the metal oxide material layer 112 includes one or more oxides of the metals such as ruthenium (Ru), iridium (Ir), lanthanum (La), nickel (Ni) or the combinations thereof. In one embodiment, the metal oxide material layer 112 includes a layer of ruthenium oxide (RuOx, 1≤x≤2), iridium oxide (IrOx, 1≤x≤2), or lanthanum nickel oxide (LaNiOx, 1≤x≤3). In one embodiment, the metal oxide material layer 112 includes a layer made of lanthanum nickel oxide (LaNiOx, 1≤x≤3).

In some embodiments, the electrode material layer 114 includes a layer containing one or more metals such as platinum (Pt), ruthenium (Ru), iridium (Ir), or combinations thereof. In some embodiments, the electrode material layer 114 includes a metallic material such as platinum (Pt) or ruthenium (Ru), a combination thereof, a composite thereof or a stack thereof. In certain embodiments, the electrode material layer 114 is or includes a platinum layer. In certain embodiments, the electrode material layer 114 is or includes a ruthenium layer. For example, the thickness of the electrode material layer 114 should be thick enough to be equivalent to or larger than 500 angstroms. In one embodiment, the thickness of the electrode material layer 114 ranges from about 500 angstroms to 2000 angstroms. In some embodiments, due to the higher resistivity of the metal oxide material, the metal oxide material layer 112 is better to be thinner than the electrode material layer 114. In some embodiments, the thickness of the electrode material layer 114 is about 1.5 times to about 5 times of the thickness of the metal oxide material layer 112. That is, a ratio of the thickness of the electrode material layer 114 to the thickness of the metal oxide material layer 112 is about 1.5 to about 5.

For example, the metal oxide material layer 112 has high oxygen activity and may function as an oxygen vacancy tailoring layer for tailoring the oxygen vacancy for the piezoelectric layer 110, and the metal oxide material layer 112 located between the piezoelectric layer 110 and the electrode material layer 114 can mitigate possible accumulation of oxygen vacancy when the piezoelectric layer 110 is in direct contact with the electrode material layer 114. Especially, when the electrode material layer 114 is or includes a pure metal material such as Pt or Ru, it is useful to arrange the metal oxide material layer 112 having oxygen vacancy compensation capability between the electrode material layer 114 and the piezoelectric layer 110, which further improves TDDB (time dependent dielectric breakdown) performance and polarization fatigue over operation cycles. In some embodiments, the composite structure of the electrode material layer 114 and the metal oxide material layer 112 may be regarded as a composite electrode stack.

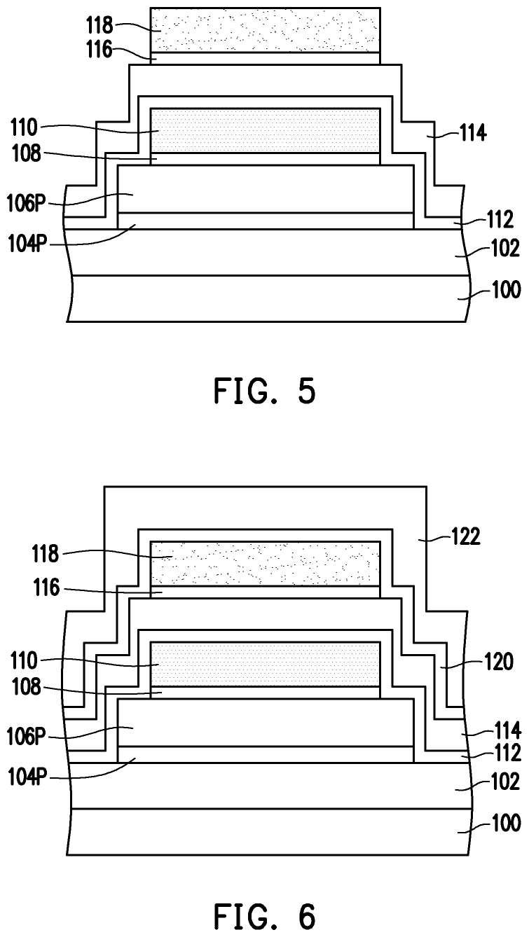

Referring to FIG. 5, in some embodiments, a buffer layer 116 is formed on the electrode material layer 114 and a piezoelectric layer 118 is then formed on the buffer layer 116. Examples of the material for the buffer layer 116 include metals such as lanthanum and nickel, oxides thereof and composite oxides thereof. In some embodiments, the buffer layer 116 includes a layer of lanthanum nickel oxide (LaNiOx, 1≤x≤3). In some embodiments, the buffer layer 116 is formed by PVD or CVD, and the buffer layer 116 may be formed as a single-layer structure of the aforementioned material(s), or a stack structure of a plurality of the aforementioned material(s).

Referring to FIG. 5, in some embodiments, the piezoelectric layer 118 includes a lead-containing piezoelectric material, and the lead-containing piezoelectric material includes lead zirconium titanate (abbreviated as PZT) with the chemical formula Pb[Zr_{X}Ti_{(1-X)}]O₃ (0<x<1), either undoped or doped with niobium (Nb), lanthanum (La), or iron (Fe). In some embodiments, the piezoelectric layer 118 is formed by, for example, PVD including sputtering, laser ablation, or PLD or CVD. In some embodiments, the piezoelectric layer 118 is formed by, for example, wet/chemical methods using so-gel or aerosol deposition and thermally annealing at a high temperature.

In some embodiments, the piezoelectric layer 110 and the piezoelectric layer 118 are made of the same material. In some embodiments, the piezoelectric layer 110 and the piezoelectric layer 118 are made of the same material but having different stoichiometric compositions. For example, the piezoelectric layer 110 includes Pb[Zr_{X1}Ti_{(1-X1)}]O₃ (0<x1<1) and the piezoelectric layer 118 includes Pb[Zr_{X2}Ti_{(1-X2)}]O₃ (0<x2<1), x1 is different from x2.

Similarly, the buffer layer 116 is formed before the formation of the piezoelectric layer 118 to provide crystalline orientation preferred for the later formed piezoelectric material of the piezoelectric layer 118. In some embodiments, among the electrode material pattern 114P, the buffer layer 116 and the piezoelectric layer 118, the material of the buffer layer 116 has the value of the lattice parameter (e.g. lattice constant a) larger than that of the material of the electrode material pattern 114P and smaller than that of the material of the piezoelectric layer 118. Through the buffer layer 116 having the orientation inducing capability, the quality of the piezoelectric layer 118 is upgraded with preferred crystal orientation and a larger piezoelectric coefficient (d₃₃) of the piezoelectric layer 118. For example, the piezoelectric layer 118 is formed with a thickness ranging from about 500 nanometers to 1000 nanometers.

Referring to FIG. 6, a metal oxide material layer 120 and an electrode material layer 122 are sequentially formed over the stack of the oxide material pattern 104P, the electrode material pattern 106P, the buffer layer 108, the piezoelectric layer 110, metal oxide material layer 112, the electrode material layer 114, the buffer layer 116 and the piezoelectric layer 118. Referring to FIG. 6, the metal oxide material layer 120 and the electrode material layer 122 are globally formed and are formed conformally covering the underlying stack (conformal to the profiles of the stack of the stack of the oxide material pattern 104P, the electrode material pattern 106P, the buffer layer 108, the piezoelectric layer 110, metal oxide material layer 112, the electrode material layer 114, the buffer layer 116 and the piezoelectric layer 118).

In some embodiments, the metal oxide material layer 120 may be formed from the similar material(s) and similar methods for forming the metal oxide material layer 112. In one embodiment, the metal oxide material layer 120 includes a layer of ruthenium oxide (RuOx, 1≤x≤2), iridium oxide (IrOx, 1≤x≤2), or lanthanum nickel oxide (LaNiOx, 1≤x≤3). In one embodiment, the metal oxide material layer 120 includes a layer made of lanthanum nickel oxide (LaNiOx, 1≤x≤3).

In some embodiments, the electrode material layer 122 may be formed from the similar material(s) and similar methods for forming the electrode material layer 114. In some embodiments, the electrode material layer 122 includes a metallic material such as platinum (Pt) or ruthenium (Ru), a combination thereof, a composite thereof or a stack thereof. In certain embodiments, the electrode material layer 122 is or includes a platinum layer. In certain embodiments, the electrode material layer 122 is or includes a ruthenium layer. For example, the thickness of the electrode material layer 122 should be thick enough to be equivalent to or larger than 500 angstroms. In one embodiment, the thickness of the electrode material layer 122 ranges from about 500 angstroms to 2000 angstroms. In some embodiments, due to the higher resistivity of the metal oxide material, the metal oxide material layer 120 is better to be thinner than the electrode material layer 122. In some embodiments, a ratio of the thickness of the electrode material layer 122 to the thickness of the metal oxide material layer 120 is about 1.5 to about 5.

Similarly, the metal oxide material layer 120 provides an oxygen-containing contact surface for tailoring oxygen vacancy for the piezoelectric layer 118, which also improves TDDB (time dependent dielectric breakdown) performance and polarization fatigue over operation cycles. In some embodiments, the composite structure of the electrode material layer 122 and the metal oxide material layer 120 may be regarded as a composite electrode stack.

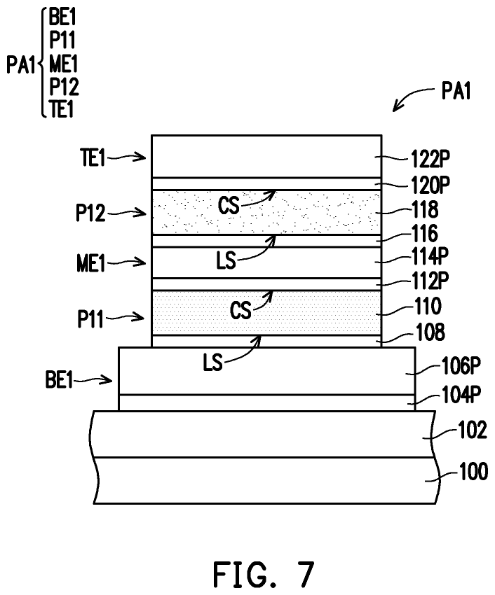

Referring to FIG. 7, a patterning process is performed to at least pattern the electrode material layers 122, 144, the metal oxide material layers 120, 112 respectively into the electrode material patterns 122P, 114P and the metal oxide material patterns 120P, 112P. In some embodiments, the patterning process includes forming a photoresist layer (not shown) with a pattern over the underlying layers, etching (e.g. dry etching) the underlying layers by transferring the pattern of the photoresist layer to pattern the underlying layers, and the photoresist layer may be subsequently removed, for example, by ashing or other suitable processes.

Referring to FIG. 7, in some embodiments, the electrode material patterns 122P, 114P and the metal oxide material patterns 120P, 112P are shown to have the same dimensions with the buffer layers 108, 116 and the piezoelectric layers 110, 118. However, it is possible that the electrode material patterns 122P, 114P and the metal oxide material patterns 120P, 112P are patterned through different patterning processes and may have different dimensions from the dimensions of the buffer layers 108, 116 and the piezoelectric layers 110, 118. The patterns of these layers may be modified and optimized to enable functionality of the various MEMS devices to be subsequently formed.

In some embodiments, referring to FIG. 7, the stack structure PA1 formed over the base insulation layer 102 or over the substrate 100 can function as a piezoelectric actuator structure, including the stack of the oxide material pattern 104P and electrode material pattern 106P (as the bottom electrode structure BE1), the stack of the buffer layer 108 and the piezoelectric layer 110 (first piezoelectric stack P11), the stack of the metal oxide material pattern 112P and electrode material pattern 114P (as the middle electrode structure ME1), the stack of the buffer layer 116 and the piezoelectric layer 118 (second piezoelectric stack P12) and the stack of the metal oxide material pattern 120P and electrode material pattern 122P (as the top electrode structure TE1) (from bottom to top).

In some embodiments, by inserting the buffer layers 108, 116 in the stack structure PA1, a lattice matching interface LS is formed between the layers 108/110 and 116/118, which attributes to the formation of high-quality piezoelectric layers or piezoelectric layers having larger piezoelectric coefficients. In some embodiments, by inserting the metal oxide material pattern 112P, 120P in the stack structure PA1, an oxygen-containing interface CS is formed between the layers 110/112P and 118/120P.

In some embodiments, as shown in FIG. 7, the stack structure PA1 including two piezoelectric layers 110, 118 is a piezoelectric bimorph structure, functioning as a biomorph piezoelectric actuator. When an electric field is applied to the two piezoelectric layers in the stack structure, one piezoelectric layer stretches along its length and the other piezoelectric layer shrinks. That is, the piezoelectric layer(s) bends and deforms when a voltage is applied to the electrodes of the stack structure. With the same dimensions or similar geometry and under the same applied electric field, a bimorph actuator can achieve more displacement than a unimorph actuator. For the MEMS devices formed with the actuator structure, such as MEMS micro speakers, the larger the displacement caused by the bimorph actuator is, the greater the sound pressure it generates. For the MEMS micro speaker devices using the bimorph actuator structure can achieve a higher sound pressure level (SPL) while keeping the aim of fabricating more micro speakers in a limited area.

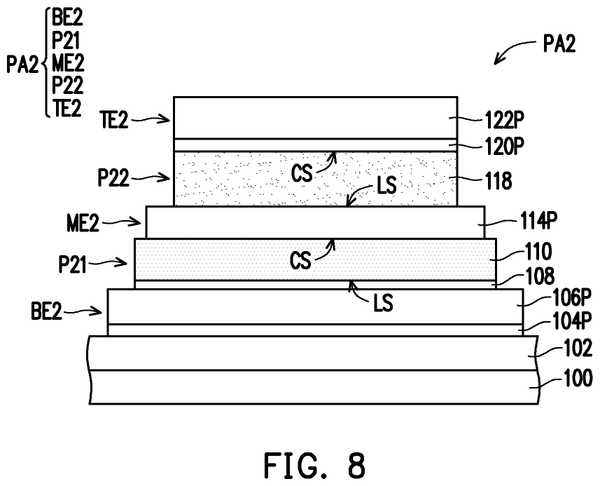

FIG. 8 is a schematic cross-sectional view showing a stacking structure for a semiconductor device according to some embodiments of the present disclosure. The exemplary structure shown in FIG. 8 may be fabricated following some or all steps of the manufacturing processes shown from FIG. to FIG. 7, the same or similar materials and methods may be used for forming respective layers or patterns and detailed descriptions will not be repeated herein. The stack structure PA2 includes certain layers, patterns or stacks substantially the same as those illustrated in FIGS. 1-7, and the same or similar parts are labelled with the same or similar reference numerals.

Referring to FIG. 8, the stack structure PA2 is formed over the base insulation layer 102 and over the substrate 100, and the stack structure PA2 includes sequentially the stack of the oxide material pattern 104P and electrode material pattern 106P (as the bottom electrode structure BE2), the stack of the buffer layer 108 and the piezoelectric layer 110 (first piezoelectric stack P21), the electrode material pattern 114P (as the middle electrode structure ME2), the piezoelectric layer 118 (second piezoelectric stack P22) and the stack of the metal oxide material pattern 120P and electrode material pattern 122P (as the top electrode structure TE2) (from bottom to top).

For the stack structure PA2, as seen in FIG. 8, the bottom electrode structure BE2 and the first piezoelectric stack P21 are respectively patterned into the same pattern while the middle electrode structure ME2 is patterned into another pattern. In some embodiments, the dimensions of the pattern of the first piezoelectric stack P21 are smaller than those of the pattern of the bottom electrode structure BE2 but larger than those of the pattern of the middle electrode structure ME2. In some embodiments, the top electrode structure TE2 and the second piezoelectric stack P22 are patterned into the same pattern having dimensions smaller than those of the pattern of the middle electrode structure ME2. In some embodiments, the stack structure PA2 may be formed as a Maya pyramid-like structure or a flat-top pyramid shaped structure. That means, the stack structure PA2 has a cross-sectional profile as descending stairs for opposite sides.

In some embodiments, the electrode material pattern 106P or 122P includes a layer of one or more metals such as platinum (Pt), ruthenium (Ru), iridium (Ir), lanthanum (La), nickel (Ni) or the oxides thereof. In some embodiments, the electrode material pattern 106P or the electrode material 122P includes a metallic material such as platinum (Pt) or ruthenium (Ru). In certain embodiments, the electrode material pattern 106P or the electrode material 122P includes a platinum layer. In certain embodiments, the electrode material pattern 106P or the electrode material 122P includes a ruthenium oxide layer. In some embodiments, the electrode material pattern 114P includes a layer of one or more metals such as platinum (Pt), ruthenium (Ru), iridium (Ir), lanthanum (La), nickel (Ni) or the oxides thereof. In some embodiments, the electrode material pattern 114P includes a conductive metal oxide material such as ruthenium oxide (RuOx, 1≤x≤2), iridium oxide (IrOx, 1≤x≤2), or lanthanum nickel oxide (LaNiOx, 1≤x≤3) or combinations thereof. In some embodiments, the electrode material pattern 114P is in direct contact with the above piezoelectric stack P22 and the below piezoelectric stack P21. In one embodiment, the electrode material pattern 114P physically contacts the piezoelectric layers 118 and 110.

In some embodiments, the piezoelectric layer 118 includes a lead-containing piezoelectric material, and the lead-containing piezoelectric material includes lead zirconium titanate (PZT, Pb[Zr_{X}Ti_{(1-X)}]O₃ (0<x<1)), either undoped or doped with niobium (Nb), lanthanum (La), or iron (Fe). In some embodiments, the piezoelectric layer 110 and the piezoelectric layer 118 may be made of the same material. In some embodiments, the piezoelectric layer 110 and the piezoelectric layer 118 are made of the same material but having different stoichiometric compositions.

In one embodiment, since the electrode material pattern 114P includes the conductive metal oxide material such as ruthenium oxide or lanthanum nickel oxide, better lattice matching exists between the electric material pattern 114P and the above piezoelectric layer 118 and no buffer layer is needed between the electrode material pattern 114P and the piezoelectric layer 118. Furthermore, as the conductive oxide material of the electrode material pattern 114P provides an oxygen-containing contact surface (interface) for the piezoelectric layers 110 and 118 and lessens oxygen vacancy accumulation for the piezoelectric layers 110 and 118, and no oxide material layer is needed between the electrode material pattern 114P and the piezoelectric layer 110. In some embodiments, for the stack structure PA2, the electrode material pattern 114P may have a resistivity higher than that of the electrode material pattern 106P or 122P, and the electrode material pattern 114P has a thickness smaller than that of the electrode material pattern 106P or 122P.

In some embodiments, the arrangement of the buffer layer 108 and the electrode material pattern 114P in the stack structure PA2, a lattice matching interface LS is formed between the layers 108/110 and 114P/118, which attributes to the formation of high-quality piezoelectric layers or piezoelectric layers having larger piezoelectric coefficients. In some embodiments, by arranging the electrode material pattern 114P and the metal oxide material pattern 120P in the stack structure PA2, an oxygen-containing interface CS is formed between the layers 110/114P and 118/120P.

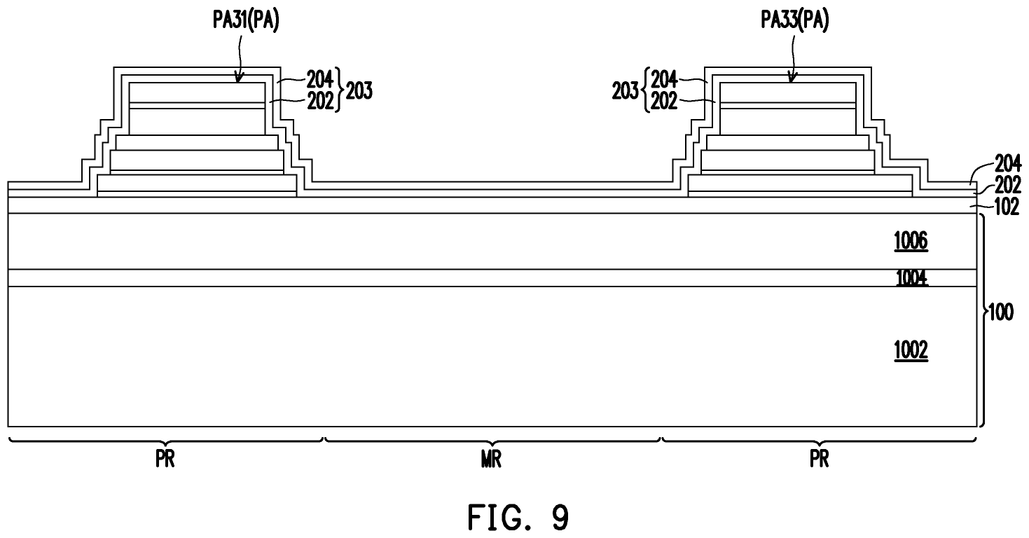

FIG. 9 to FIG. 11 illustrate schematic cross-sectional views showing a structure at various stages of a manufacturing method for forming a semiconductor MEMS device according to some embodiments of the present disclosure. FIG. 12 is a schematic top view of an exemplary structure with MEMS devices arranged in arrays in accordance with embodiments of the present disclosure.

Referring to FIG. 9, in some embodiments, the structure 9M includes a stack structure PA formed on base insulation layer 102 over the substrate 100. Herein, the substrate 100 is similar to or substantially the same as the substrate 100 illustrated in the previous paragraphs, and the same or similar parts are labelled with the same reference numerals, and the stack structure PA over the substrate 100 may be obtained through the manufacturing processes as described in the previous paragraphs. In some embodiments, the substrate 100 is or includes a silicon-on-insulator (SOI) substrate, silicon-germanium on insulator (SGOI) or a germanium-on-insulator (GOI) substrate. In one embodiment, the substrate is provided as a SOI wafer containing an insulator layer 1004 sandwiched between below and above silicon layers 1002 and 1006. For example, the stack structure PA may be the same or similar to the stack structure PA1 or PA2 as illustrated in the previous contexts, and the schematic cross-sectional views as seen from FIG. 1 to FIG. 7 or in FIG. 8 merely illustrate a portion of the stack structure. Also, the schematic cross-sectional views seen from FIG. 9 to FIG. 11 merely illustrate a portion of the MEMS devices 9M arranged in arrays in the structure 12 shown in FIG. 12.

In some embodiments, referring to FIG. 9 and FIG. 12, the stack structure PA may be initially formed as a ring shape over the substrate 100. In some embodiments, the stack structure PA is substantially the same as the stack structure PA2 and has a cross-sectional view of a flat-top pyramid shaped structure. The exemplary stack structure PA may be fabricated following some or all steps of the manufacturing processes shown from FIG. to FIG. 7, and the same or similar materials and methods may be used for forming respective layers or patterns and detailed descriptions will not be repeated herein. The stack structure PA includes substantially the same layers, patterns or stacks as the stack structure PA2 and the same or similar parts are labelled with the same or similar reference numerals.

Referring to FIG. 9 and FIG. 12, the ring-shaped stack structure PA includes four portions PA31, PA32, PA33 and PA34, and these four portions PA31-PA34 are initially formed as continuous and connected portions and later will be separated by the formation of slits. Referring to the schematic cross-sectional view of FIG. 9, the left portion of the stack structure PA corresponds to the first portion PA31, while the right portion of the stack structure PA corresponds to the third portion PA33. It is understood that the layers and patterns of the stack structure PA are shown to provide relative stacking or laminating relationships but the construction of the stacked structure should not be limited by the configurations of the layers and patterns therein.

In some embodiments, after formation of the stack structure PA on the base insulation layer 102 over the substrate 100, an insulative material 203 is blanketly formed over the base insulation layer 102 and the substrate 100 conformally covering the stack structure PA. In some embodiments, the insulative material 203 is formed as a composite layer of an aluminum oxide layer 202 and a silicon oxide layer 204. In some embodiments, the silicon oxide layer 204 may include TEOS oxide, which is an oxide material formed by decomposition of tetraethylorthosilicate (TEOS). In some embodiments, the aluminum oxide may be formed by PVD or CVD with a thickness ranging from 50 nm to 200 nm, and the silicon oxide layer 204 is formed by CVD (such as thermal CVD) with a thickness ranging from about 200 nm to 1000 nm, although other suitable thicknesses may be employed. In some embodiments, the aluminum oxide layer 202 of the insulative material 203 may function as etch stop layer for forming contact openings.

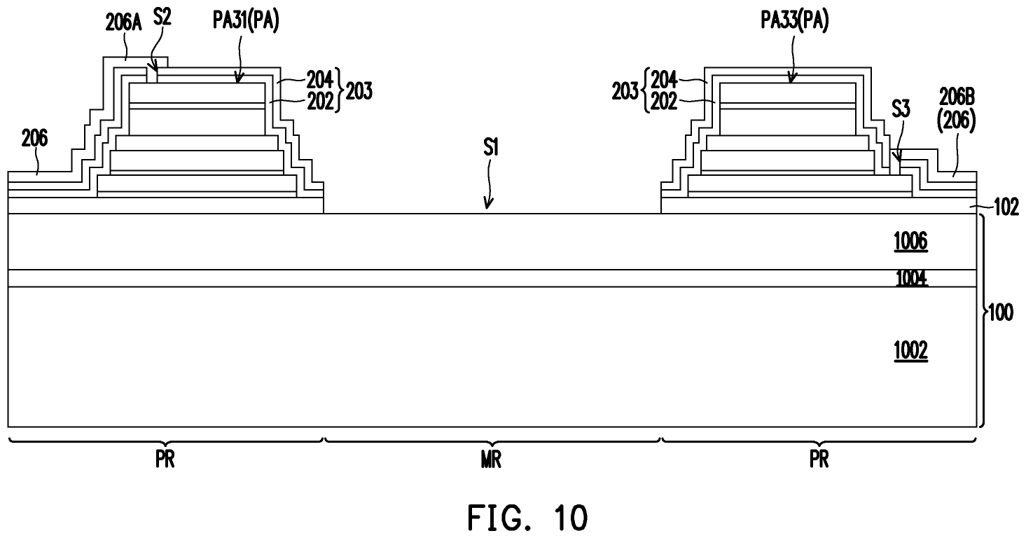

Referring to FIG. 10, a first patterning process is performed to partially remove the base insulation layer 102 and the insulative material 203 to form at least one opening S1 to expose the underlying silicon layer 1006 (e.g. silicon surface) and to define the membrane region MR. In some embodiments, the membrane region MR is located in the middle and surrounded by the peripheral region PR where the stack structure PA is mainly located therein. In some embodiments, the base insulation layer 102 and the insulative material 203 within the membrane region MR are removed to expose the underlying silicon layer 1006, and referring to FIG. 12, the membrane region MR may be defined with a top-view of a paper windmill shape and is enclosed by the stack structure PA. In some embodiments, the first patterning process includes similar processes as described aforementioned, and the base insulation layer 102 and the insulative material 203 may be patterned through different patterning processes or one single patterning process or any other suitable processes may be implemented.

Referring to FIG. 10, in some embodiments, openings S2 and S3 are formed in the insulative material 203 respectively expose the electrode material pattern 106P and the electrode material pattern 122P. In some embodiments, the openings S2 and S3 are contact openings. Later, a contact layer 206 is formed with a first contact 206A and a second contact 206B respectively filling in the openings S2 and S3 and on the insulative material 203. In some embodiments, the contact layer 206 includes a metallic material containing copper (Cu), titanium (Ti), and/or aluminum (Al). In one embodiment, the contact layer 206 is a composite layer of Ti/AlCu/Ti. In some embodiments, the contact layer 206 may include a single metal layer or a composite layer comprising a plurality of sub-layers formed of different metallic materials, formed by PVD, CVD or plating. For example, the contact layer 206 is formed by CVD or sputtering and later patterned to form the first contact 206A and the second contact 206B.

In some embodiments, the first contact 206A physically contacts and electrically connects with the top electrode material pattern 122P, while the second contact 206B that is discrete and separate from the first contact 206A physically contacts and electrically connects with the bottom electrode material pattern 106P. Although not expressly shown, the middle electrode material pattern 114P may be electrically connected with other component and may be grounded, and the top and bottom electrode material patterns 122P and 106P may be applied with a voltage at the same time.

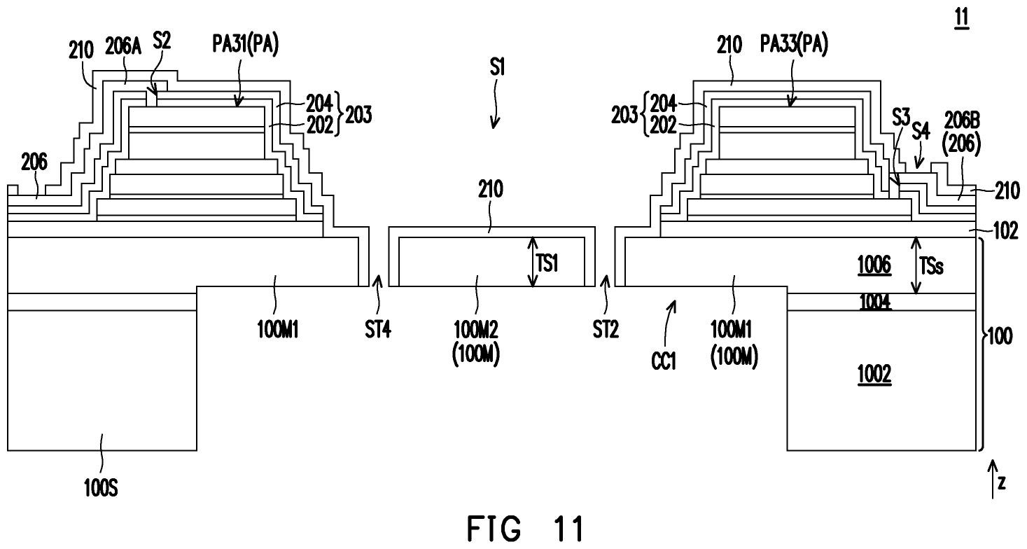

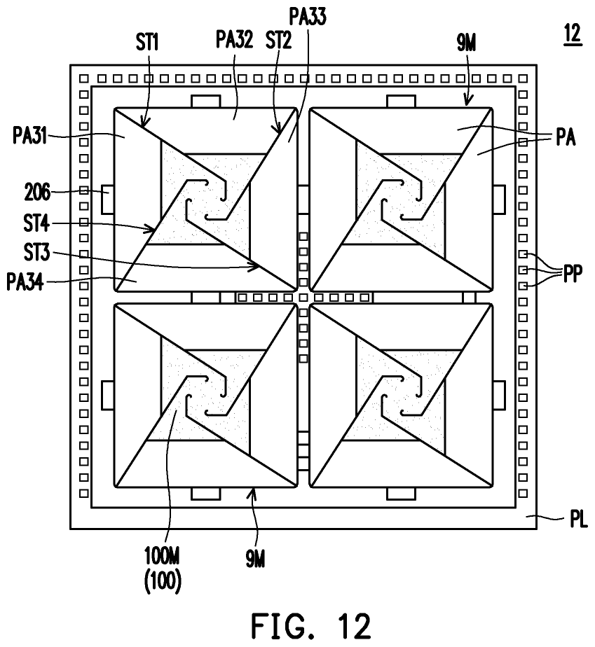

Referring to FIG. 11 and FIG. 12, in some embodiments, a second patterning process is performed to form slits ST1-ST4 as trenches penetrating though the stack structure PA and the above layer(s) 203 and penetrating into the substrate 100 with a suitable depth (from the top surface of the silicon layer 1006) by performing at least one anisotropic etching process such as reactive ion etching (RIE). Referring to FIG. 11 and FIG. 12, the slits ST1-ST4 define the membrane (or diaphragm) and piezoelectric actuator structure(s). From the top view of FIG. 12, the stack structure PA is divided into four sections PA31, PA32, PA33 and PA34, spaced apart and separated, by the slits ST1-ST4. However, the arrangement of the slits ST1-ST4 is designed to have slits ST1-ST4 extending from the peripheral region PR into the membrane region MR in four different directions without meeting one another, and from the top view, the four slits ST1-ST4 are slant to one another but do not intersect one another. By doing so, the membrane (or diaphragm) can be driven or actuated by different sections PA31-PA34 of the stack structure PA.

In some embodiments, referring to FIG. 11, a passivation layer 210 is formed over the patterned stack structure (over the separate sections PA31-PA34) and over the slits ST1-ST4. In some embodiments, the passivation layer 210 is formed blanketly over the whole structure conformally covering the portions PA31-PA34 and conformally covering the sidewalls of the slits ST1-ST4. In some embodiments, the passivation layer 210 includes a nitride material such as silicon nitride, and the passivation layer 210 may be formed by CVD. For later processing, in some embodiments, openings S4 may be formed in the passivation layer 210 to expose the contact layer 206 for further electrical connection.

Later, referring to FIG. 11, a backside etching process is performed to the substrate 100 to form a cavity CC1 by removing portions of the substrate 100 (including silicon layer 1004, the insulator layer 1004 and the silicon layer 1006) from the backside of the substrate 100 (from the bottom surface of the silicon layer 1002). In some embodiments, the span of the cavity CC1 extends beyond the membrane region MR and extends into the peripheral region PR (see FIG. 11). In some embodiments, the insulator layer 1004 may function as a stopper layer during the backside etching process, and the silicon layer 1002 and the insulator layer 1004 are respectively etched through different etching processes and sequentially removed during the backside etching process. in some embodiments, the backside etching process includes one or more reactive ion etching (RIE) processes. Through the backside etching process and the formation of the cavity CC1, the substrate 100 is etched to form a membrane 100M and a support structure (support frame) 100S located below the membrane 100M and surrounding the membrane 100M. In some embodiments, the structure 11 includes at least the membrane 100 M (as diaphragm) overlying the support frame 100S and across the cavity CC1, the stack structure PA (as piezoelectric actuator) disposed on the membrane 100M and the support frame 100S enclosing and defining an acoustic chamber (i. e. the cavity CC1). Depending on the span of the cavity CC1, the membrane 100M may include an outer portion 100M1 that is located directly below the stack structure PA and an inner (central) portion 100M2 located between the slits ST1-ST4.

From the cross-sectional view of FIG. 11, even though the slits ST1-ST4 cut through the membrane 100M in the thickness direction, the membrane 100M is still a continuous layer as one piece (stilled connected in the central part as seen in FIG. 12). That is, the slits ST1-ST4 do not cut the membrane 100M into unconnected pieces but merely penetrates through the membrane 100M in the thickness direction (z-direction), which releases the membrane 100M and increase the flexibility of the movement. For example, the cavity CC1 functions as an acoustic chamber or space. In some embodiments, the cavity CC1 is formed with a depth large enough so that the insulator layer 1004 and the silicon layer 1002 within the span of the cavity CC1 are removed and the silicon layer 1006 is partially etched to have a remained thickness TS1. In some embodiments, the remained thickness TS1 is smaller than the thickness TSs of the silicon layer 1006. In some embodiments, depending on the material used for the membrane, the thickness TS1 of the membrane 100M is suitably small so that the membrane 100M is flexible and moveable. As mentioned above, the slits ST1-ST4 are formed to cut into the substrate 100 with a suitable depth, and such suitable depth is larger than the remained thickness TS1 so that the slits ST1-ST4 cut through the membrane 100M in the thickness direction.

For example, the membrane 100M may not be a separate member from the substrate 100, but a portion of the substrate 100 may be processed to be sufficiently thin and used as the elastic membrane. For example, the material of the membrane 100M includes a semiconductor material such as silicon. In other embodiments, depending on the type of the substrate 100 provided, the material of the membrane 100M may include germanium, silicon-germanium or other semiconductor material. Alternatively, instead of removing a portion of the substrate 100 to form the membrane, an elastic film may be formed below the piezoelectric stack structure PA as the diaphragm.

Referring to FIG. 11 and FIG. 12, in some embodiments, the structure 12 includes multiple MEMS devices 9M that are mounted on and electrically connected with a circuit substrate PL with pads PP. In some embodiments, the MEMS devices 9M are electrically connected with the circuit substrate PL through the conductive connectors. In some embodiments, the circuit substrate PL includes a printed circuit board (PCB) and the pads PP are arranged along the peripheral region of the circuit substrate PL may be applicable for further electrical connection. Available fabrication processes for the circuit substrate PL and for pad fabrication in any laminated substrate or circuit substrate may be used.

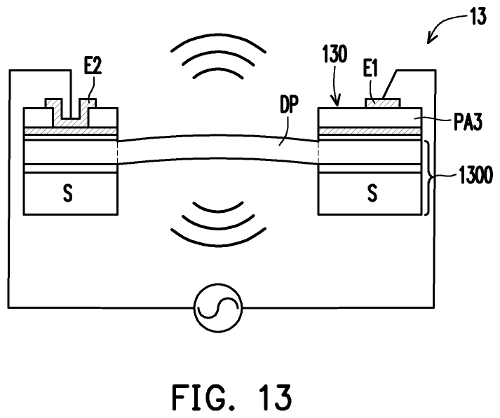

FIG. 13 is a schematic illustration of working principles of an exemplary MEMS micro speaker structure in accordance with embodiments of the present disclosure.

Referring to FIG. 13, a ring-shaped piezoelectric actuator element 130 including top electrode contact E1, bottom electrode contact E2 and the piezoelectric stack structure PA3 sandwiched there-between is located on the membrane potion (i.e. diaphragm DP) of the substrate 1300. Herein, the piezoelectric stack structure PA3 is illustrate as one layer for illustration purposes and for simplicity, however, it is understood that the stack structures PA, PA1 or PA2 may be applicable as the piezoelectric stack structure PA3 for the actuator element 130. In some embodiments, through the driving electrodes E1, E2, when an electric field E (or a voltage AV) is applied on the electrodes E1, E2, a strain & is introduced in the piezoelectric layer(s) of the stack structure PA3 (piezoelectric transduction), and the strain in the piezoelectric layer(s) will bend and cause deformation of the stack structure PA3 and lead to the motion or movement of the central diaphragm (mechanical transduction). Furthermore, the moving diaphragm (or membrane) will push the air to generate a sound wave (expressed as parallel arcs in FIG. 13) (acoustic transduction). In some embodiments, the structure 13 is or includes a MEMS device and may function as a MEMS micro speaker. For example, the structure 13 includes the piezoelectric actuator element 130 (as actuator), the membrane portion DP (as diaphragm) and the support portion S of the substrate 1300 (as a support frame enclosing the acoustic chamber).

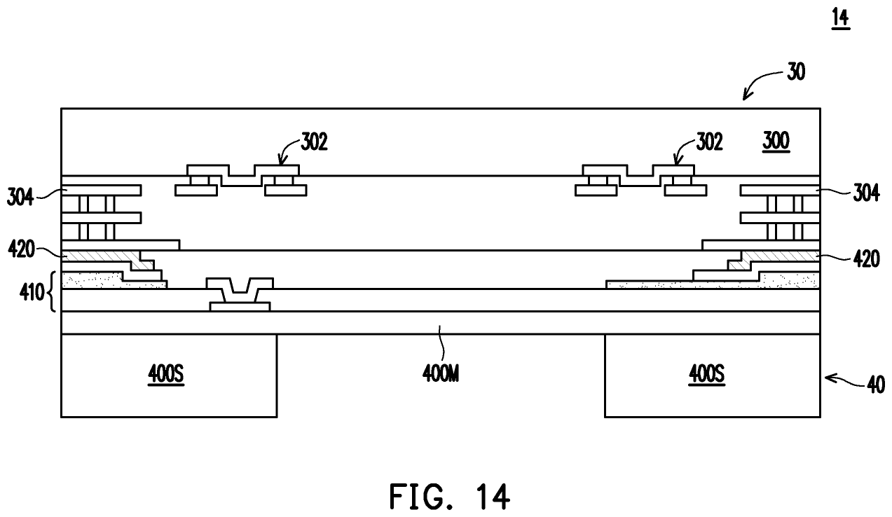

FIG. 14 is a schematic cross-sectional view of an exemplary structure having MEMS devices connected with a device wafer in accordance with some embodiments of the present disclosure.

Referring to FIG. 14, in some embodiments, the integrated structure 14 includes a device wafer 30 connected with a MEMS wafer structure 40 including a plurality of MEMS devices though bonding connectors 420. In some embodiments, the device wafer 300 includes a semiconductor substrate 300, transistors 302 formed on or in the semiconductor substrate 300 and interconnection structures 304 configured to electrically interconnect the transistors 302 and connect the transistors 302 with other devices (such as MEM devices) or other components. In some embodiments, the MEMs wafer structure 40 includes a stack structure 410 with a plurality of MEMS devices formed therein, and some or all of the MEMS devices may have substantially the same or similar stacking layers and configurations as the structure 13 of FIG. 13, or the structure 11 of FIG. 11 or even the stack structures PA, PA1 and PA2.

In some embodiments, the bonding connectors 420 include conductive metallic materials formed by electroplating or deposition, such as aluminum, titanium, copper, nickel, cobalt, tungsten, nitrides thereof, alloys thereof or combinations thereof. In some embodiments, the bonding connectors 420 include metallic pads, posts and/or under-bump metallization (UBM) patterns or other suitable patterned metallic layers. It is understood that the metallization patterns of the bonding connectors 420 may have different dimensions or pitches.

As described above, the MEMS devices may be formed in a wafer form as a MEMS wafer structure and then bonded with one or more device wafers and/or device dies. Furthermore, it is possible that the MEMS devices are formed at different levels such as the level of the front-end-of-line manufacturing processes or back-end-of-line manufacturing processes but in a different portion of a semiconductor wafer for fabricating semiconductor devices.

In some embodiments, through the arrangement of specific metal oxide material layer(s) in the stack structure of the MEMS device to provide an oxygen-containing contact surface (or interface) between the piezoelectric layer and the adjacent electrode material layer(s), for the MEMS device(s) including such piezoelectric stack structure, better TDDB (time dependent dielectric breakdown) performance and less polarization fatigue are achieved. As a result, the MEMS devices, such as MEMS micro speakers, using the piezoelectric stack structure is proven to have extended device lifetime and enhanced performance.

In some embodiments of the present disclosure, a stack structure is provided. The piezoelectric stack structure comprises a first electrode material layer, a first piezoelectric layer disposed over the first electrode material layer, a second electrode material layer disposed over the first piezoelectric layer, a second piezoelectric layer disposed over the second electrode material layer, and a third electrode material layer disposed over the second piezoelectric layer. A first oxygen-containing interface is formed between the first piezoelectric layer and the second electrode material layer, and a first lattice-matching interface is formed between the first piezoelectric layer and the first electrode material layer. A second oxygen-containing interface is formed between the second piezoelectric layer and the third electrode material layer, and a second lattice-matching interface is formed between the second piezoelectric layer and the second electrode material layer.

In some embodiments of the present disclosure, a device structure is provided. The device structure includes a moveable membrane, a support structure, disposed below the membrane and defining and encircling a chamber below the membrane, and a stack structure disposed on the membrane. The stack structure comprises a first electrode layer, a first piezoelectric layer disposed over the first electrode layer, a second electrode layer disposed over the first piezoelectric layer, a second piezoelectric layer disposed over the second electrode layer, and a third electrode layer disposed over the second piezoelectric layer. A first oxygen-containing interface is formed between the first piezoelectric layer and the second electrode layer, and a first lattice-matching interface is formed between the first piezoelectric layer and the first electrode layer, and a second oxygen-containing interface is formed between the second piezoelectric layer and the third electrode layer, and a second lattice-matching interface is formed between the second piezoelectric layer and the second electrode layer.

In some embodiments of the present disclosure, a method for forming a stack structure includes the following process steps. A first electrode material layer is formed. A first piezoelectric layer is formed over the first electrode material layer and a first lattice-matching interface between the first piezoelectric layer and the first electrode material layer is formed. A second electrode material layer is formed over the first piezoelectric layer, and a first oxygen-containing interface between the first piezoelectric layer and the second electrode material layer is formed. A second piezoelectric layer is formed over the second electrode material layer, and a second lattice-matching interface between the second piezoelectric layer and the second electrode material layer is formed. A third electrode material layer is formed over the second piezoelectric layer, and a second oxygen-containing interface between the second piezoelectric layer and the third electrode material layer is formed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A piezoelectric stack structure, comprising:
a first electrode material layer;
a first piezoelectric layer disposed over the first electrode material layer;
a second electrode material layer disposed over the first piezoelectric layer;
a second piezoelectric layer disposed over the second electrode material layer; and
a third electrode material layer disposed over the second piezoelectric layer,
wherein a first oxygen-containing interface is formed between the first piezoelectric layer and the second electrode material layer, and a first lattice-matching interface is formed between the first piezoelectric layer and the first electrode material layer, and a second oxygen-containing interface is formed between the second piezoelectric layer and the third electrode material layer, and a second lattice-matching interface is formed between the second piezoelectric layer and the second electrode material layer.

2. The structure of claim 1, further comprising a first buffer layer disposed between the first electrode material layer and the first piezoelectric layer, and a material of the first buffer layer includes lanthanum nickel oxide.

3. The structure of claim 2, wherein the material of the first buffer layer has a lattice parameter larger than that of a material of the first electrode material layer and smaller than that of a material of the first piezoelectric layer.

4. The structure of claim 2, further comprising a second buffer layer disposed between the second electrode material layer and the second piezoelectric layer, and a material of the second buffer layer includes lanthanum nickel oxide.

5. The structure of claim 4, wherein the material of the second buffer layer has a lattice parameter larger than that of a material of the second electrode material layer and smaller than that of a material of the second piezoelectric layer.

6. The structure of claim 1, further comprising a first metal oxide material layer disposed between the second piezoelectric layer and the third electrode material layer, and a material of the first metal oxide material layer includes ruthenium oxide, iridium oxide, or lanthanum nickel oxide.

7. The structure of claim 6, further comprising a second metal oxide material layer disposed between the first piezoelectric layer and the second electrode material layer, and a material of the second metal oxide material layer includes ruthenium oxide, iridium oxide, or lanthanum nickel oxide.

8. The structure of claim 1, wherein a material of the first piezoelectric layer or the second piezoelectric layer includes undoped lead zirconium titanate, or lead zirconium titanate doped with niobium (Nb), lanthanum (La), or iron (Fe).

9. The structure of claim 8, wherein the first piezoelectric layer and the second piezoelectric layer includes lead zirconium titanate having different stoichiometric compositions.

10. A device structure, comprising:
a moveable membrane;
a support structure, disposed below the membrane and defining and encircling a chamber below the membrane;
a stack structure disposed on the membrane, the stack structure comprising:
a first electrode layer;
a first piezoelectric layer disposed over the first electrode layer;
a second electrode layer disposed over the first piezoelectric layer;
a second piezoelectric layer disposed over the second electrode layer; and
a third electrode layer disposed over the second piezoelectric layer,
wherein a first oxygen-containing interface is formed between the first piezoelectric layer and the second electrode layer, and a first lattice-matching interface is formed between the first piezoelectric layer and the first electrode layer, and a second oxygen-containing interface is formed between the second piezoelectric layer and the third electrode layer, and a second lattice-matching interface is formed between the second piezoelectric layer and the second electrode layer.

11. The structure of claim 10, further comprising a first buffer layer disposed between the first electrode layer and the first piezoelectric layer, and a material of the first buffer layer includes lanthanum nickel oxide.

12. The structure of claim 11, further comprising a second buffer layer disposed between the second electrode layer and the second piezoelectric layer, and a material of the second buffer layer includes lanthanum nickel oxide.

13. The structure of claim 10, wherein the third electrode layer comprises a first electrode material layer and a first metal oxide material layer disposed between the second piezoelectric layer and the first electrode material layer, and a material of the first metal oxide material layer includes ruthenium oxide, iridium oxide, or lanthanum nickel oxide.

14. The structure of claim 13, wherein the second electrode layer comprises a second electrode material layer and a second metal oxide material layer disposed between the first piezoelectric layer and the second electrode material layer, and a material of the second metal oxide material layer includes ruthenium oxide, iridium oxide, or lanthanum nickel oxide.

15. The structure of claim 10, wherein the stack structure is arranged in a ring-shape located directly above and surrounding the moveable membrane.

16. A method for forming a stack structure, comprising:
forming a first electrode material layer;
forming a first piezoelectric layer disposed over the first electrode material layer and forming a first lattice-matching interface between the first piezoelectric layer and the first electrode material layer;
forming a second electrode material layer disposed over the first piezoelectric layer, and forming a first oxygen-containing interface between the first piezoelectric layer and the second electrode material layer;
forming a second piezoelectric layer disposed over the second electrode material layer, and forming a second lattice-matching interface between the second piezoelectric layer and the second electrode material layer; and
forming a third electrode material layer disposed over the second piezoelectric layer, and forming a second oxygen-containing interface between the second piezoelectric layer and the third electrode material layer.

17. The method of claim 16, wherein forming a first lattice-matching interface between the first piezoelectric layer and the first electrode material layer includes forming a first buffer layer between the first electrode material layer and the first piezoelectric layer, and a material of the first buffer layer includes lanthanum nickel oxide.

18. The method of claim 17, wherein forming a second lattice-matching interface between the second piezoelectric layer and the second electrode material layer includes forming a second buffer layer between the second electrode material layer and the second piezoelectric layer, and a material of the second buffer layer includes lanthanum nickel oxide.

19. The method of claim 16, wherein forming a second oxygen-containing interface between the second piezoelectric layer and the third electrode material layer includes forming a first metal oxide material layer disposed between the second piezoelectric layer and the third electrode material layer, and a material of the first metal oxide material layer includes ruthenium oxide, iridium oxide, or lanthanum nickel oxide.

20. The method of claim 19, wherein forming a first oxygen-containing interface between the first piezoelectric layer and the second electrode material layer includes forming a second metal oxide material layer disposed between the first piezoelectric layer and the second electrode material layer, and a material of the second metal oxide material layer includes ruthenium oxide, iridium oxide, or lanthanum nickel oxide.
